(19) United States
(12) Patent Application Publication
(10) Pub. No.: US 2014/0238478 A1
(43) Pub. Date: Aug. 28, 2014

(54) BACK JUNCTION SOLAR CELL WITH ENHANCED EMITTER LAYER

(71) Applicant: SUNIVA, INC., Norcross, GA (US)

(72) Inventors: Daniel L Meier, St. Marys, PA (US); Xiaoyan Wang, Cupertino, CA (US); Adam M Payne, Dunwoody, GA (US); Atul Gupta, Dunwoody, GA (US)

(73) Assignee: SUNIVA, INC., Norcross, GA (US)

(21) Appl. No.: 13/781,069

(22) Filed: Feb. 28, 2013

(51) Int. Cl. H01L 31/0224

(52) U.S. Cl. CPC H01L 31/022458
USPC 136/256; 438/72

(57) ABSTRACT

Back junction solar cells having improved emitter layer coverage and methods for their manufacture are disclosed. In one embodiment, a back junction solar cell includes an n-type base layer having an emitter layer formed from a first p-type doped region (e.g., formed by liquid phase epitaxial regrowth) and a second p-type doped region (e.g., formed by ion implantation) that extends beyond the first region. In various embodiments, this configuration permits the first p-type doped region to be formed with a border between it and the edges of the wafer (e.g., to prevent inadvertent shunting of the cell), while the second p-type doped region extends the emitter layer to improve emitter layer coverage. In certain embodiments, the second doped p-type region may extend to the edges of the wafer's n-type base layer.

### BACKGROUND OF THE INVENTION

1. Field of the Invention

Various embodiments of the present invention relate generally to solar cells. In particular, various embodiments of the present invention are directed to a back junction solar cell having a full coverage rear emitter, and methods for its manufacture.

2. Description of Related Art

In basic design, a solar cell is composed of a material such as a semiconductor substrate that absorbs energy from photons to generate electricity through the photovoltaic effect. When photons of light penetrate into the substrate, the energy is absorbed and an electron previously in a bound state is freed. The released electron and the previously occupied hole are known as charge carriers.

The substrate is generally doped with p-type and n-type impurities to create an electric field inside the solar cell at a p-n junction. In order to use the free charge carriers to generate electricity, the electrons and holes must not recombine before they can be separated by the electric field at the p-n junction. The electrons will then be collected by the electrical contacts on the n-type emitter layer and the holes will be collected by the electrical contacts on the p-type substrate. The charge carriers that do not recombine are available to power a load.

A common method for producing solar cells begins with a substrate doped to have p-type conductivity. An n-type dopant is introduced to the front surface of the substrate to form an n-type emitter layer on top of a p-type base layer. Typically, the substrate is moderately doped with dopant of p-type conductivity, while the emitter layer is heavily doped with dopant of n-type conductivity. As a result of forming the emitter layer, a p-n junction is formed near the illuminated surface of the substrate (i.e., the front side of the substrate exposed to the light source when the solar cell is in use). Solar cells of this type are generally referred to as “front junction” cells.

However, conventional front junction cells have been known to suffer from various disadvantages, including low minority carrier diffusion length in the base of the cell and shunting of the p-n junction due to penetration of the p-n junction during contact formation. To overcome these disadvantages, certain techniques have been suggested for forming a “back junction” solar cell, in which the cell's p-n junction is formed near the back surface of the cell instead of the front. For example, U.S. Pat. No. 6,262,359 describes a solar cell having an n-type substrate with a more heavily doped n⁺ layer on the front side of the cell, which serves to create a front surface field, and a doped p⁺ layer formed using aluminum on the back side of the cell, which functions as a p⁺ emitter. Such aluminum alloy back junction cells are generally desirable for their ability to provide low series resistance and high fill factors.

However, typical aluminum alloy back junction cells have a performance disadvantage stemming from the limited coverage of their rear emitter layer. In forming the rear emitter layer, an aluminum paste is commonly screen-printed on the back surface of an n-type silicon wafer to form an aluminum back contact. When the back contact is heated or fired (e.g., in a belt furnace), the aluminum-doped p⁺ silicon emitter layer is formed by liquid phase epitaxial regrowth on the n-type base layer proximate its interface with the back contact. Due to imperfections inherent in screen printing technologies and other methods of aluminum paste application, the aluminum back contact is generally applied such that a border exists between the outer edges of the wafer and the edges of the aluminum back contact (e.g., 1 mm). This border is generally provided as a safety tolerance to ensure aluminum is not deposited beyond the edges of the wafer, which may cause aluminum to wrap around the edges of the wafer, thereby shorting the solar cell and rendering it inoperable. In addition, the border helps to ensure aluminum is not deposited in undesirable areas of the screen-printing apparatus.

The cross-sectional area of the aluminum-doped emitter layer generally corresponds to the cross-sectional area of the heated aluminum back contact (as used herein, the term “cross-sectional area” shall refer to the area of a horizontal cross-section parallel to the base of the solar cell). For this reason, the above-described techniques will generally result in the emitter layer not extending to the edges of the wafer (e.g., such that a border exists between the edges of the emitter layer and edges of the wafer). As a result, coverage of the emitter layer across the back side of the wafer is limited, typically to around 97% of the cross-sectional area of the wafer.

To increase emitter layer coverage of convention aluminum alloy rear junction cells, certain techniques have been suggested for removing the edges of the wafer not covered by the cell's aluminum back contact. For example, the article entitled “Aluminum-Doped p⁺ Silicon for Rear Emitters and Back Surface Fields: Results and Potentials of Industrial n- and p-Type Solar Cells” by Christian Schmiga, et al., presented at the 25^{th} European PV Solar Energy Conference and Exhibition, 6-10 Sep. 2010 in Valencia, Spain, suggests cutting off 1 mm wafer edges that have remained uncovered during screen-printing of the aluminum paste on the rear surface of an aluminum alloy rear junction cell to improve cell efficiency from 18.6% to 19.3%. By cutting off these wafer edges, the cell's aluminum emitter coverage was increased from 97% to 100%. The cutting steps required by this method, however, can be expensive, time consuming, and potentially destructive to the cell. In addition, valuable silicon is wasted in the cut strips.

Accordingly, there is a need in the art for an improved back junction solar cell having increased emitter layer coverage and a method for manufacturing such a cell that overcomes the above-described disadvantages and deficiencies of previous technologies.

### BRIEF SUMMARY OF THE INVENTION

Various embodiments of the present invention are directed to a solar cell of the back junction type having an emitter layer opposite an illuminated surface of the solar cell. According to various embodiments, the solar cell comprises a silicon substrate defining an n-type base layer and a p-type emitter layer underlying the n-type base layer so as to define a p-n junction at the interface of the p-type emitter layer and the n-type base layer; and an aluminum back contact layer underlying the p-type emitter layer. In various embodiments, the p-type emitter layer comprises at least one first region comprising aluminum dopant, wherein the area of the at least one first region at least partially overlaps the area of the aluminum back contact layer when viewed from beneath the back contact layer; and at least one second region comprising a p-type dopant, at least a portion of the area of the at least one second region extending beyond the area of the at least one first region when viewed from beneath the back contact layer. In addition, according to various embodiments the p-type emitter layer may cover the full back surface of the n-type base layer. Furthermore, in certain embodiments, the back contact layer may define a border area between the outer edges of the back contact layer and the outer edges of the n-type base layer such that the at least one first region is defined within the edges of the n-type base layer; and the at least one second region may surround the first region and extends to each outer edge of the n-type base layer. In certain embodiments, the cross-sectional area of the at least one first region is substantially aligned with the cross-sectional area of the back contact layer when viewed from beneath the back contact layer.

In addition, various embodiments of the present invention are directed to a solar cell of the back junction type having an emitter layer opposite an illuminated surface of the solar cell, the solar cell comprising an n-type base layer; a p-type emitter layer underlying the n-type base layer; and a back contact layer underlying the p-type emitter layer. In various embodiments, the p-type emitter layer comprises at least one first region doped with a first p-type dopant, wherein the area of the at least one first region at least partially overlaps the area of the back contact layer when viewed from beneath the back contact layer; and at least one second region doped with a second p-type dopant, at least a portion of the area of the at least one second region extending beyond the area of the at least one first region to one or more outer edges of the n-type base layer when viewed from beneath the back contact layer.

In addition, various embodiments of the present invention are directed to a method for forming a solar cell of the back junction type. According to various embodiments, the method comprises the steps of providing a n-type doped substrate to serve as an n-type base layer; and fabricating a p-type emitter layer underlying the n-type base layer. In various embodiments, the step of fabricating the p-type emitter layer comprises doping at least one first region of a back surface of the substrate with a p-type dopant, the area of the at least one first region extending to one or more outer edges of the n-type base layer; applying an aluminum back contact layer to the back surface of the substrate; and alloying the aluminum back contact layer with at least one second region of the back surface of the substrate, the at least one second region being defined substantially within the perimeter of the at least one first region. In certain embodiments, the contact layer is applied such that a border is defined between the outer edges of the contact layer and the outer edges of the n-type base layer, and the at least one second region is defined within the edges of the n-type base layer. In addition, in certain embodiments, the at least one first region surrounds the at least one second region and extends to each of the outer edges of the n-type base layer.

The above summary is provided merely for purposes of summarizing some example embodiments of the invention so as to provide a basic understanding of some aspects of the invention. Accordingly, it will be appreciated that the above described example embodiments should not be construed to narrow the scope or spirit of the invention in any way more restrictive than as defined by the specification and appended claims. It will be appreciated that the scope of the invention encompasses many potential embodiments, some of which will be further described below, in addition to those here summarized.

### BRIEF DESCRIPTION OF THE DRAWINGS

Having thus described embodiments of the invention in general terms, reference will now be made to the accompanying drawings, which are not necessarily drawn to scale, and wherein:

FIG. 1 illustrates a cross-sectional side view of a back junction solar cell according to one embodiment of the present invention;

FIG. 2a illustrates a flowchart of initial operational steps carried out according to an example embodiment of a method for manufacturing a back junction solar cell of the present invention;

FIG. 2b illustrates a flowchart of further operational steps carried out according to an example embodiment of a method for manufacturing a back junction solar cell of the present invention;

FIG. 2c illustrates a flowchart of further operational steps carried out according to an example embodiment of a method for manufacturing a back junction solar cell of the present invention;

FIG. 3 illustrates a bottom plan view of a back junction solar cell according to one embodiment of the present invention.

### DETAILED DESCRIPTION

Various embodiments of the present invention will now be described more fully hereinafter with reference to the accompanying drawings, in which some, but not all embodiments of the invention are shown. Those skilled in this art will understand that the invention may be embodied in many different forms and should not be construed as limited to the embodiments set forth herein; rather, these embodiments are provided so that this disclosure will satisfy applicable legal requirements. Like reference numerals refer to like elements throughout.

As used herein, embodiments in which a first element is described to be “overlying,” “over,” or “above” a second element may generally be taken to signify that the first element is closer to the primary illuminated surface or primary illumination source. For example, if a first element is said to be overlying a second element, the first element may be closer to the sun. Similarly, embodiments in which a first element is described to be “underlying,” “under,” and “below” a second element may generally be taken to signify that the first element is further from the primary illuminated surface or primary illumination source. For example, if a first element is said to be underlying a second element, the first element may be further from the sun. In addition, it should be noted that, in various embodiments, the primary illumination source may not refer to other forms of secondary illumination, such as light returning to the device from a reflective surface located behind or beyond the device after the light originating from the primary illumination source has passed through or around the device.

Various embodiments of the present invention are generally directed to a back junction solar cell having improved emitter layer coverage and methods for manufacturing the same. According to various embodiments, the back junction solar cell includes a rear emitter layer comprised of a pair of p⁺ doped regions that, together, provide increased emitter layer coverage. As an example, certain embodiments of the back junction solar cell include an n-type base layer having one region lightly doped with boron and another region doped with aluminum. The aluminum-doped p⁺ silicon emitter region may be formed from an aluminum back contact via liquid phase epitaxial regrowth and, for the reasons discussed above, is generally provided on the back surface of the n-type base layer such that a border exists between it and the outer edges of the silicon wafer. However, in various embodiments, the boron-doped p⁺ silicon emitter region may be provided on the full back surface of the n-type base layer (or only in the border regions) such that the portions of the n-type base layer not covered by the aluminum-doped p⁺ silicon emitter region are covered by the boron-doped p⁺ silicon emitter region. In such embodiments, this structure extends the rear emitter layer to the edges of the wafer and improves the emitter layer coverage. Indeed, in some embodiments, no border exists between the emitter layer and the edges of the wafer.

The combination of the aluminum-doped p⁺ silicon emitter region and the boron-doped p⁺ silicon emitter region provides an emitter layer with improved coverage over the rear surface of the n-type base layer. For example, certain embodiments have an emitter layer with 100% coverage of the back surface of the wafer.

### Back Junction Solar Cell

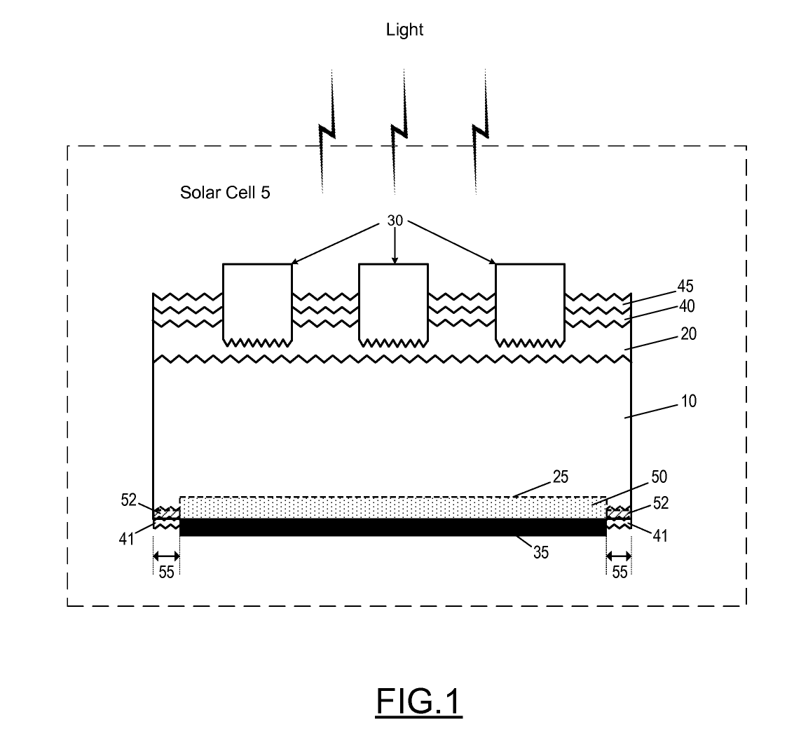

FIG. 1 illustrates one embodiment of a solar cell 5 in accordance with the present invention. According to various embodiments, the solar cell 5 may be formed of a semiconductor substrate. The substrate may be composed of silicon (Si), germanium (Ge) or silicon-germanium (SiGe) or other semiconductive material, or it may be a combination of such materials. In the case of monocrystalline substrates, the semiconductor substrate may be grown from a melt using Float Zone (FZ) or Czochralski (Cz) techniques. The resulting mono-crystalline boule may then be sawn into a wafer to form the substrate. For a substrate composed of silicon, germanium or silicon-germanium, the crystallographic orientation of the wafer surface may be (100) or (110), for example. Alternatively, the substrate can be multi-crystalline, which may be less expensive than monocrystalline substrates. However, the multi-crystalline substrate suffers from recombination of charge carriers at crystal grain boundaries, and requires passivation to avoid efficiency losses.

In certain embodiments, the front and back surfaces of the substrate may define pyramidal structures created by their treatment with a solution of potassium hydroxide (KOH) and isopropyl alcohol (IPA) during an anisotropic etching process. The presence of these structures increases the amount of light entering the solar cell 5 by reducing the amount of light that is lost by reflection from the front surface. The pyramidal structures on the back surface beneath the back contact may be destroyed during formation of a back contact.

According to the embodiment of FIG. 1, the substrate may be doped with impurities of n-type conductivity, to create an n-type base layer 10. If the substrate is composed of silicon (Si), germanium (Ge) or silicon-germanium (Si—Ge), the n-type base layer 10 may be doped with phosphorus (P), antimony (Sb), arsenic (As) or other Group V elements to induce n-type conductivity. A front surface field layer 20 may be formed on the front surface of the n-type base layer 10, for example by ion implantation. According to various embodiments, the front surface field layer 20 may be doped with impurities of the same n-type conductivity as that of the n-type base layer 10. In certain embodiments, the same type dopant atoms as the n-type base layer may be used. In the illustrated embodiment of FIG. 1, the front surface field layer 20 is a uniform front surface field layer. According to other embodiments, the front surface field layer 20 may comprise a selective front surface field layer comprised of heavily doped selective regions and lightly doped field regions. In such embodiments, the selective front surface field layer may be provided as described in U.S. Publication No. 2011/0139231, the entirety of which is hereby incorporated by reference.

The front surface of the front surface field layer 20 and back surface of the n-type base layer 10 represent a discontinuity in their crystalline structures, and dangling chemical bonds are present at these exposed surfaces. The dangling bonds constitute recombination centers which disadvantageously annihilate charge carriers, thus lowering the efficiency of the solar cell. In the illustrated embodiment, oxide layers 40, 41 are formed on both the front surface of the front surface field layer 20 and the back surface of a p⁺ silicon emitter region 52 to prevent the annihilation of charge carriers. In doing so, a passivating oxide layer may form on the entire exposed wafer surface, including on the thin sides of the wafer that define its thickness.

The oxide layers 40, 41 may contact the front surface of the front surface field layer 20 and the back surface of the p⁺ silicon emitter region 52 in order to chemically satisfy the bonds of the atoms at these interfaces so that they will not annihilate charge carriers. The oxide layers 40, 41 may comprise a dielectric material such as silicon dioxide (SiO₂) for a silicon substrate, or an oxide of another semiconductor type, depending upon the composition of the substrate. The oxide layers 40, 41 may have thicknesses in a range from 5 to 150 nanometers. For example, in one embodiment, 20 nanometers may be used. By passivating the dangling silicon bonds on the surfaces of the substrate, the oxide layers 40, 41 may reduce the surface recombination velocity and decrease the front surface field component of the reverse saturation current density (Jₒₑ), thus improving the overall efficiency of the solar cell 5. Additionally, in certain embodiments, the oxide layer 41 formed on the back surface of the p⁺ silicon emitter region 52 may advantageously produce a high-quality, dielectric-passivated back surface, for example when capped with a silicon nitride layer.

An antireflection layer 45 may be formed on the front surface of the front oxide layer 40 to reduce reflection of the incident light and thus loss of solar energy. The antireflection layer 45 may have a refractive index greater than that of the oxide layer 40, which tends to cause light incident to the solar cell to refract into the antireflection layer 45 and through the oxide layer 40 to the substrate where it can be converted to free charge carriers. For example, the antireflection layer 45 may have an index of refraction in the range of 1.4 to 2.4 when measured with an incident laser having a wavelength of 632.8 nm. The antireflection layer 45 may be composed of silicon nitride (Si₃N₄), aluminum oxide (Al₂O₃), titanium oxide (TiO₂), magnesium fluoride (Mg₂F), zinc oxide (ZnO), or zinc sulfide (ZnS₂), or combinations of these materials. In some embodiments, the antireflection layer 45 comprises an amorphous nitride, such as amorphous silicon nitride (a-SiN_{X}). The antireflection layer 45 may have a thickness from 10 to 100 nanometers.

In addition, front contacts 30 and front connections may be formed of conductive materials such as silver (Ag). Generally, for silicon and other substrates, silver may be used to contact the surface of the substrate that is doped n-type, such as the front surface field layer 20. Direct contact of metal to a semiconductor increases the recombination rate of electrons and holes, which can significantly lower solar cell efficiency. To decrease this effect and limit the proportion of metal covering the surface of the substrate, the front contacts 30 and front connections may be configured as point or line contacts (sometimes called “local contacts”). The spacing and arrangement of point or line contacts can be determined as described in U.S. Publication No. 2009/0025786 published Jan. 29, 2009, which is incorporated by reference as if set forth in full herein.

The front contacts 30 and front connections may be formed by screen-printing the silver on the front surface of the antireflection layer 45. The front connections may comprise solderable pads or bus bars to facilitate electrical connections to the front surface of the solar cell 5. According to example embodiments, the pattern of the front connections may be aligned with the pattern of the back connections described below.

In addition, for the front contacts 30 and front connections, silver may be selected because of its high electrical conductivity to limit shadowing effects that can lower solar cell efficiency. Various commercial silver pastes are available for this purpose. However, silver is not transparent, so it may be desirable to limit the dimensions of the front contacts 30 and front connections to point or line contacts of limited area for this additional reason. As noted above, in certain embodiments, the front surface field layer 20 may be a selective front surface field layer comprised of heavily doped selective regions and lightly doped field regions. In addition, according to such embodiments, the front contacts 30 may be positioned and configured as described in the above-referenced '231 publication.

In accordance with certain embodiments, the oxide layer 40 and the antireflection layer 45 may be disposed on the front surface of the front surface field layer 20 prior to forming the front contacts 30 and front connections. In this case, the front contacts 30 and front connections may physically penetrate the oxide layer 40 and the antireflection layer 45 to make contact with the underlying regions of the front surface field layer 20. The front contacts 30 and front connections may contain glass frit in addition to metal to facilitate their firing through the oxide layer 40 and the antireflection layer 45 to make contact with the front surface field layer 20.

As shown in FIG. 1, the solar cell 5 also includes an emitter layer formed near the back surface of the n-type base layer 10. In the illustrated embodiment, the emitter layer is comprised of an aluminum-doped p⁺ silicon emitter region 50 and a boron-doped p⁺ silicon emitter region 52. The aluminum-doped p⁺ silicon emitter region 50 is formed along nearly the entire back surface of the n-type base layer 10, with the exception of a border region 55 defined near the outer edges of the n-type base layer 10. For example, in one embodiment, the border region 55 is defined along all sides of the aluminum-doped p⁺ silicon emitter region 50 such that no portion of the aluminum-doped p⁺ silicon emitter region 50 extends to the outer edges of the n-type base layer 10. In one embodiment, the border 55 has a width of 1 mm defined between the outer edges of the aluminum-doped p⁺ silicon emitter region 50 and the outer edges of the n-type base layer 10. However, according to various other embodiments, the border 55 may be provided in other widths, and may be defined such that its width is uniform or not uniform.

As shown in FIG. 1, the boron-doped p⁺ silicon emitter region 52 is also defined along the back surface of the n-type base layer 10. However, the boron-doped p⁺ silicon emitter region 52 extends across the border region 55 to the outer edges of the n-type base layer 10. As such, in the illustrated embodiment of FIG. 1, the boron-doped p⁺ silicon emitter region 52 extends beyond the aluminum-doped p⁺ silicon emitter region 50 and fully surrounds the aluminum-doped p⁺ silicon emitter region 50 such that the aluminum-doped p⁺ silicon emitter region 50 is defined within the outer edges of the boron-doped p⁺ silicon emitter region 52. Accordingly, in the illustrated embodiment of FIG. 1, the aluminum-doped p⁺ silicon emitter region 50 and the boron-doped p⁺ silicon emitter region 52, together, form an emitter layer covering the full back surface of the n-type base layer 10.

As described in greater detail below, in one embodiment, the boron-doped p⁺ silicon emitter region 52 may be first formed on the full back surface of the n-type base layer 10 (e.g., by uniform ion implantation along the full back surface), and the aluminum-doped p⁺ silicon emitter region 50 may be formed thereafter (e.g., by liquid phase epitaxial regrowth). In such embodiments, the region in which the boron-doped p⁺ silicon emitter region 52 and the aluminum-doped p⁺ silicon emitter region 50 overlap may comprise both boron p⁺ dopants and aluminum p⁺ dopants. In other embodiments, the boron-doped p⁺ silicon emitter region 52 may be formed only on a region of the n-type base layer 10 that is not occupied by the on the full back surface of the n-type base layer 10 (e.g., only within the border region 55). In addition, according to some embodiments, variations in the width or profile of the border region 55 may result in portions of the aluminum-doped p⁺ silicon emitter region 50 extending to one or more outer edges of the n-type base layer 10, thereby resulting in the boron-doped p⁺ silicon emitter region 52 surrounding most, but not all, of the aluminum-doped p⁺ silicon emitter region 50.

Referring back to FIG. 1, a p-n junction 25 is formed at the interface between the n-type base layer 10 and the p⁺ silicon emitter regions 50, 52 near the back side of the solar cell 5. Because of their opposite conductivities, the n-type base layer 10 and the p⁺ silicon emitter regions 50, 52 create an electric field across the p-n junction 25, which separates free electrons and holes resulting from absorption of light photons and forces them to move in opposite directions to respective front and back contacts 30, 35. In addition, as discussed above, various embodiments of the emitter layer formed by the p⁺ silicon emitter regions 50, 52 cover the full back surface of the n-type base layer 10. In such embodiments, the p-n junction 25 will be provided across the full back surface of the n-type base layer 25, thereby providing 100% emitter layer coverage. As noted above, providing the p-n junction 25 across the full back surface of the n-type base layer 25 has been shown to increase the short circuit current density (J_{sc}) and cell efficiency.

The solar cell 5 also includes a back contact 35. According to various embodiments, the back contact 35 may comprise an aluminum back contact 35 (e.g., composed of an aluminum-silicon eutectic composition having a thickness from 10 to 50 micrometers). In various embodiments, the back contact 35 may be formed on the back surface of the n-type base layer 10 using screen-printed pastes. As noted above, the aluminum-doped p⁺ silicon emitter region 50 may be formed by liquid phase epitaxial regrowth at the interface of the n-type base layer 10 and an aluminum back contact 35. As such, the cross-sectional area of the aluminum-doped p⁺ silicon emitter region 50 is generally aligned with the cross-sectional area of the back contact 35 when viewed from beneath the back contact 35. For example, in the illustrated embodiment of FIG. 1, the back contact 35 covers nearly the entire back surface of the n-type base layer 10, but is not printed over the narrow border region 55 defined near the outer edges of the n-type base layer 10. In such an embodiment, the back contact 35 may comprise a layer of aluminum covering approximately 90 to 99% (e.g., 97%) of the rear surface area of the wafer. In addition, the back contact 35 may be formed continuously over back surface of the wafer (e.g., without openings or other discontinuities to form the back contact 35 around other contacts, such as silver contacts).

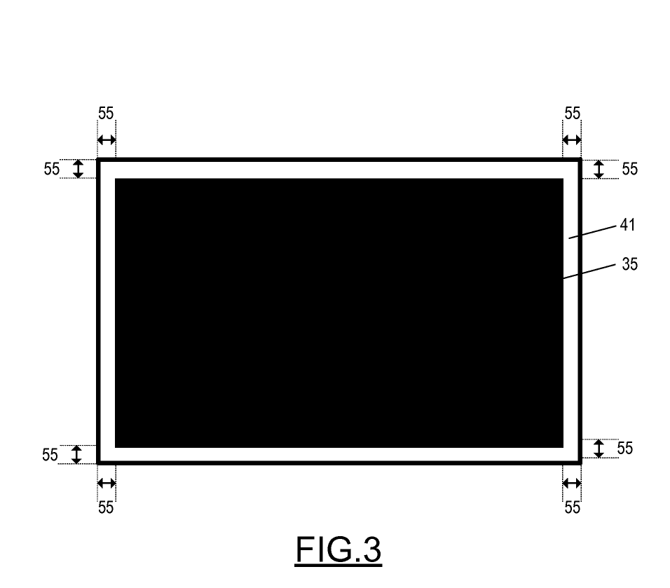

As an example, FIG. 3 shows the solar cell 5 as viewed from beneath the back contact 35. In the illustrated embodiment, the back contact 35 is formed continuously over the back surface of the wafer. The border region 55 is defined in the area between the outer edges of the back contact 35 and the outer edges of the wafer. As such, the passivating oxide layer 41 can be seen in the area of the border region 55. Moreover, as will be appreciated by viewing FIG. 3 in conjunction with FIG. 1, the boron-doped p⁺ silicon emitter region 52 is defined on top of the oxide layer 41 in alignment with the area of the border region 55.

According to various embodiments, the back contact 35 may make electrical contact with the aluminum-doped p⁺ silicon layer 50. In certain embodiments, the back contact 35 may also serve as a reflective back layer for the solar cell 5. Having a reflective back layer provides a reflective surface to return incident light reaching the back to the substrate where it can generate free charge carriers. In addition, as described in greater detail in relation to certain embodiments below, a rear oxide layer may be disposed on the back surface of the n-type base layer 10 prior to forming the back contact 35. In this case, the back contact 35 may physically penetrate the rear oxide layer to make contact with the associated p-type layer 50. The rear oxide layer may be consumed by glass frit in the paste during formation of the back contact 35.

In various embodiments, back connections—such as solderable pads or bus bars—may be formed on the back contact 35 to facilitate electrical connections to the back surface of the solar cell 5. For example, the back connections may be formed on the back contact 35 by applying copper foil on the back contact 35. In other embodiments, copper strips can be deposited (e.g., by a plasma process or by a sputtering process). In on embodiment, these cooper strips may be deposited as described in U.S. Publication No. 2012/0279563, which is herein incorporated by reference. In yet another embodiment, the back connections may be formed on the back contact 35 by applying silver soldering pads on the back of the back contact 35 (e.g., polymer silver soldering pads). In yet another embodiment, a solderless interconnect method capable of bonding directly to the aluminum back contact 35 may be used, such as a conductive film. Other embodiments may involve screen-printing a lift-off paste. Yet another alternative embodiment involves the deposition of solderable metal pads on the back aluminum surface by a plasma coating process.

As will be appreciated from the description herein, various changes and modifications to the solar cell 5 are contemplated as being within the scope of the present invention. For example, in certain embodiments, the region 52 may comprise a boron-doped silicon layer deposited on the back surface of the n-type base layer 10 (e.g., by Innovalight ink, or by epitaxial regrowth). In yet another embodiment, other boron-doped layers could be deposited (e.g., boron glass deposited by APCVD or PECVD). In addition, various embodiments of the solar cell 5 may be provided in which the regions 50, 52 are doped with other p⁺ dopants. For example, in certain embodiments, the region 52 may be doped with indium, gallium, or aluminum (e.g., by ion implantation or diffusion). In addition, the region 50 may be doped with gallium or indium. Furthermore, according to various embodiments, the profile of the border region 55 may vary according to various embodiments. As an example, certain portions of the aluminum-doped p⁺ silicon emitter region 50 may extend to one or more edges of the wafer (e.g., due to the accuracy of certain emitter formation processes). Similarly, certain portions of the boron-doped p⁺ silicon emitter region 52 may not cover certain portion of the border region 55 (e.g., also due to the accuracy of certain emitter formation processes). In such embodiments, however, the coverage of the emitter layer may nevertheless be advantageously improved, even where emitter layer coverage is less than 100%. As such, various embodiments described herein are not strictly limited to cells having 100% emitter layer coverage.

### METHOD for Manufacturing a Back Junction Solar Cell

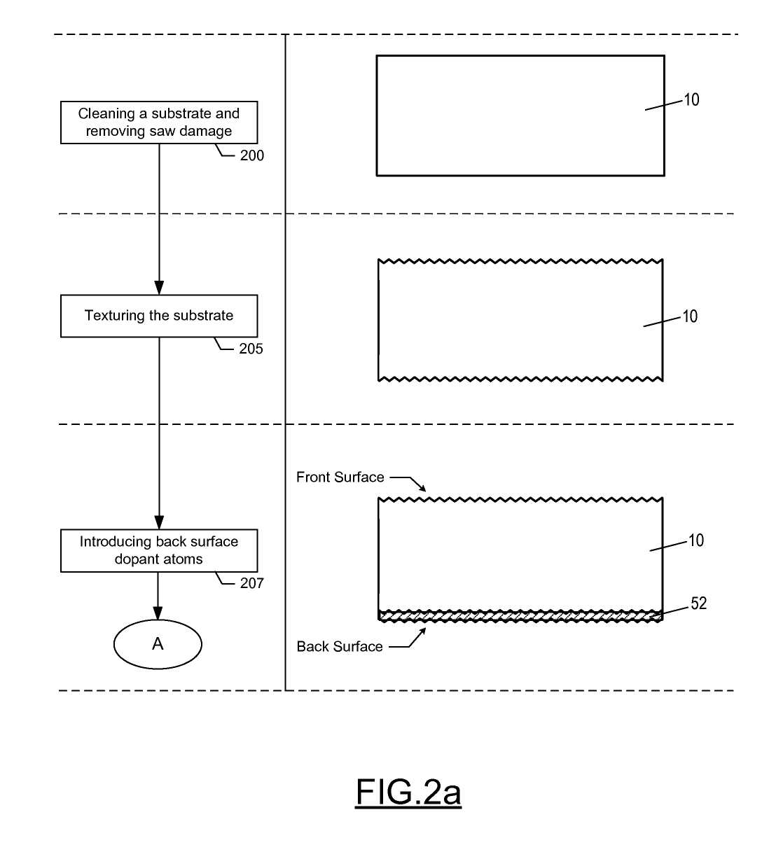

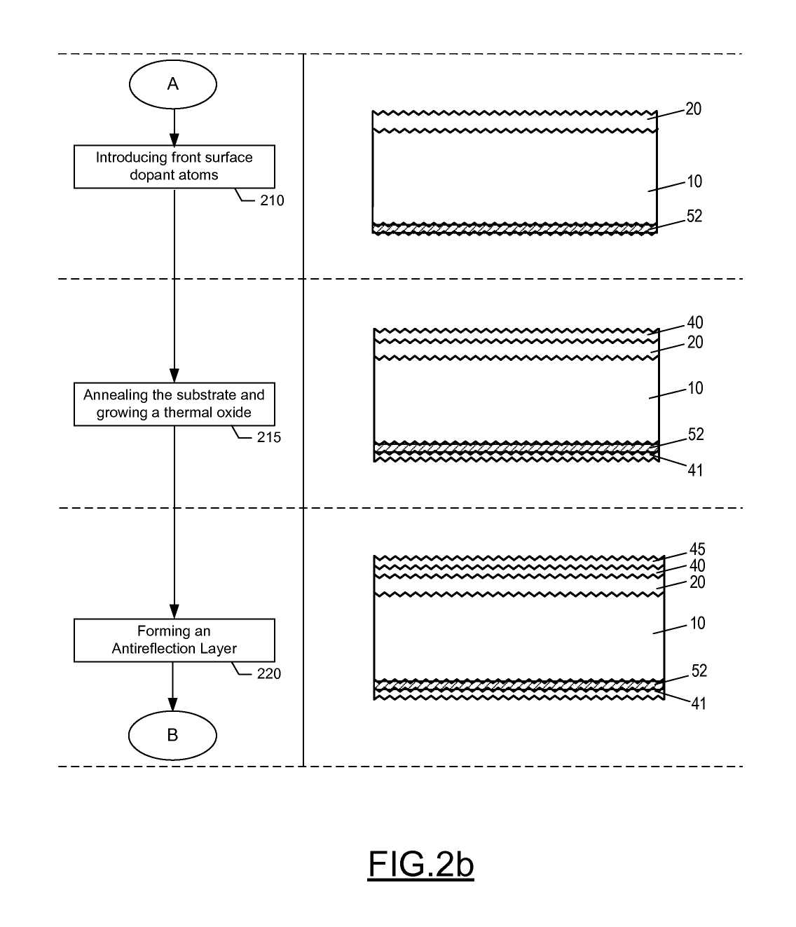

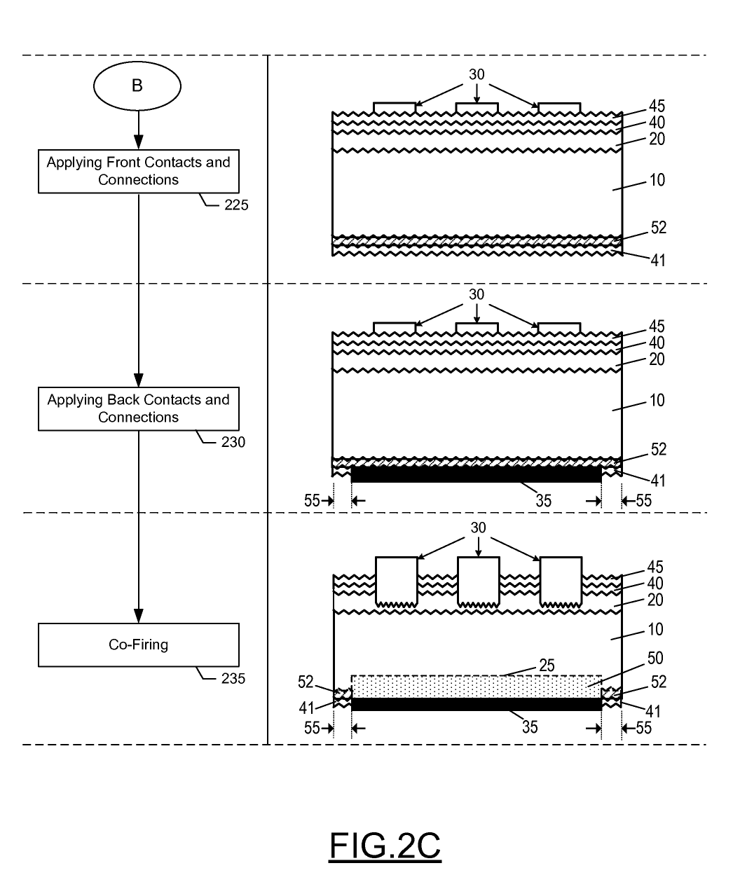

FIGS. 2a-2c illustrate a flowchart according to an example method for manufacturing the back junction solar cell 5 according to an example embodiment of the present invention. FIGS. 2a-2c thus disclose methods for manufacture in accordance with the present invention.

As shown in FIG. 2a, the exemplary method begins at operation 200, where a substrate is provided (e.g., a 156 mm psuedosquare wafer). The substrate may be as described above with respect to FIG. 1. Normally, a substrate can be ordered from suppliers with a specified amount of n-type conductivity. According to various embodiments, the substrate may be doped with n-type dopant to form an n-type base layer 10. The dopant concentration may be, for example, in a range from 10¹³ to 10²¹ atoms per cubic centimeter (atoms/cm³). The thickness of the substrate may be in a range from 50 to 500 μm. In certain embodiments, savings of semiconductor material can be achieved by using substrates with a thickness from 50 to less than 200 μm. Resistivity of the substrate may be in a range from 1 to 150 Ohm-cm, with excellent results obtained using 10 to 100 Ohm-cm. Monocrystalline or multicrystalline, or possibly string ribbon or other types of substrates, may be used.

At operation 200, the substrate may be cleaned to prepare it for processing. The cleaning may be accomplished by immersion of the substrate in a bath of potassium hydroxide (KOH) having, for example, about a 1-10% concentration, to etch away saw damage on the surfaces of the substrate. According to some example embodiments, etching may be conducted at a temperature from about 60 to 90 degrees Celsius.

Next, at operation 205, the substrate may be textured. For example, the substrate may be textured by anisotropically etching it by immersion in a bath of potassium hydroxide and isopropyl alcohol (KOH—IPA). According to some example embodiments, the potassium hydroxide concentration may be about a 1-10% concentration, and the isopropyl alcohol may be about a 2-20% concentration. The temperature of the KOH—IPA bath may be about 65 to 90 degrees Celsius. The KOH—IPA etches the surfaces of the substrate to form pyramidal structures with faces at the <111> crystallographic orientation. The resulting pyramidal structures help to reduce reflectivity at the front surface and to trap light within the substrate where it can be absorbed for conversion to electric energy.

Next, at operation 207, the boron-doped region 52 of the cell's emitter layer may be formed by an unmasked boron implant into the entire back surface of the n-type base layer 10. For example, in the illustrated embodiment, the entire back surface of the n-type base layer 10 is doped with boron by ion implantation. As an example, according to certain embodiments, the dopant dose of the ion implant may be relatively light (e.g., between 1×10¹⁴ to 2×10¹⁵ Boron atoms per square centimeter (atoms/cm²)). However, as noted above, other embodiments of the solar cell 5 may include a boron-doped region 52 provided on only a portion of the back surface of the base layer 10. In such embodiments, step 207 may be executed by a masked boron implant. The boron implant energy may be, for example, between 5 and 30 keV.

According to various other embodiments, the boron-doped region 52 may be formed in step 207 by diffusion. In yet another embodiment, a boron-doped silicon layer could be deposited on the back surface of the n-type base layer 10 (e.g., by Innovalight ink, or by epitaxial growth). In yet another embodiment, other boron-doped layers could be deposited (e.g., boron glass deposited by APCVD or PECVD). In addition, according to various other embodiments, the region 52 may be doped with p-type dopants other than boron (e.g., indium, gallium, or aluminum) using the techniques described above.

Referring now to FIG. 2b, the method proceeds to operation 210, where dopant atoms are introduced to the front surface of the n-type base layer 10 to form the front surface field layer 20. According to various embodiments, the dopant atoms may be introduced by ion implantation. The dopant atoms may have n-type conductivity like that of the n-type base layer 10. In certain embodiments, the n-type dopant may be phosphorus ions, for example P³¹⁺, or the like. According to various embodiments, the ion implantation may be performed uniformly over the n-type base layer 10 at a dose from about 0.7×10¹⁵ atoms/cm² to 7.0×10¹⁵ atoms/cm², for example 3.4×10¹⁵ atoms/cm². Beam acceleration may be performed at a range of 5 kiloelectron-volts (keV) to 30 keV, for example 10 keV. As noted above, according to various embodiments, the ion implantation step of operation 210 may be carried out so as to form a uniform front surface field layer 20. However, according to various other embodiments, operation 210 may be executed to provide a selective front surface field layer using, for example, the techniques described in U.S. Publication No. 2011/0139231.

Next, at operation 215, the implanted substrate may be subjected to a heating step to form the front surface field layer 20 and the boron-doped emitter region 52. According to some embodiments, the substrate may be introduced into a furnace for annealing, for example an automated quartz tube furnace. The inner diameter of the quartz tube may be about 290 millimeters to accommodate 156 millimeter pseudosquare substrates. The annealing operation 215 may be used to accomplish several objectives at once. First, the annealing operation 215 may activate the implanted dopant ions, that is, the heat energy of the anneal operation creates vacancies in the silicon lattice for the dopant ions to fill. Second, the annealing may drive the dopant ions deeper, for example to a desired junction depth, into the substrate. Third, the annealing operation 215 may repair damage to the crystalline lattice of the substrate 10 caused by ion implantation. Fourth, the annealing operation 215 may be used to grow passivating oxide layers 40, 41 on the front surface field layer 20 and the back surface of the boron-doped emitter region 52.

According to example embodiments, the annealing operation 215 may begin by loading 1 to 100 substrates into a furnace at a temperature in the range of 500 to 1100 degrees Celsius. In some embodiments, a large number of substrates may be simultaneously loaded into the furnace, for example up to 800 substrates may be loaded during a single furnace cycle. Once the substrates are loaded into the furnace, the temperature may be ramped up to a temperature in the range of 700 to 1100 degrees Celsius, for example from 900 to 950 degrees Celsius, over a period of 10 to 30 minutes. This temperature may then be maintained for 10 to 30 minutes, preferably 25 minutes. During this time, while the temperature is being maintained, oxygen may be introduced to the furnace, for example oxygen gas or water vapor may be introduced. The introduction of oxygen may occur for 10 to 30 minutes, preferably 10 minutes. The oxygen may be introduced at a flow rate of 100 to 5000 standard cubic centimeters per minute (sccm). The introduced oxygen may grow in situ passivating oxide layers 40, 41 on the front surface field layer 20 and the back surface of the boron-doped emitter region 52, because the use of ion implantation rather than diffusion does not result in the formation of a glass layer that would need to be removed prior to forming an oxide layer. Finally, the temperature may be ramped down to a temperature in the range of 500 to 700 degrees Celsius over a period of 30 to 120 minutes. The substrates may then be removed from the furnace.

Next, at operation 220, an antireflection layer 45 may be formed on the front passivating oxide layer 40. The antireflection layer 45 may have an index of refraction higher than the oxide layer 40 but lower than the silicon substrate, thus enabling more light to pass into the antireflection layer 45 and through the oxide layer 40 to the substrate where it can be converted to free charge carriers. The antireflection layer 45 may be composed of silicon nitride (Si₃N₄), aluminum oxide (Al₂O₃), titanium oxide (TiO₂), magnesium fluoride (Mg₂F), or zinc sulfide (ZnS₂), or combinations of these materials. In certain embodiments, the antireflection layer 45 may comprise an amorphous nitride, such as amorphous silicon nitride (a-SiN_{X}). The antireflection layer 45 may be formed by plasma enhanced chemical vapor deposition (PECVD). Alternatives to the PECVD process may include low pressure chemical vapor deposition (LPCVD), sputtering, and the like. The PECVD process may include heating the substrate to a temperature in the range of 400 to 450 degrees Celsius. Additionally, the PECVD process may include using silane and ammonia reactant gases. The antireflection layer 45 may have a thickness from 50 to 90 nanometers and an index of refraction of about 2. The thickness and index of refraction of the antireflection layer 40 may be determined by parameters such as deposition time, plasma power, flow rate of reactant gasses, and the deposition pressure.

Referring now to FIG. 2c, the method continues to operation 225, where the material for the front contacts 30 and front connections of the solar cell 5 may be applied to the front surface of the antireflection layer 45. According to various embodiments, the front contacts 30 and front connections may be screen-printed using a semi-automatic screen printer with optical alignment. The front contacts 30 and front connections may be applied using a silver paste. In some embodiments, the silver paste may be a fritted silver paste to help penetrate the front passivating oxide layer 40 and the antireflection layer 45 during firing of the contacts. The silver paste may be optimized specifically for forming contacts to the front surface field layer with low phosphorus doping. The configuration and spacing of the front contacts 30 and front connections may be defined by the contact pattern of the screen. In certain embodiments, the front contacts 30 can be 50 to 150 micrometers in width and spaced apart by 1.5 to 2.5 millimeters. The paste for the front contacts 30 and the front connections may be subsequently dried with a belt furnace. Alternatively, the front contacts 30 and front connections may be dried simultaneously with the back contact 35, as described in operation 230 below. In embodiments in which the front surface field layer 20 is a selective front surface field layer, the front contacts 30 may be positioned and configured as described in the above-referenced '231 publication.

Next, at operation 230, the material for the back contact 35 may be applied to the back surface of the boron-doped emitter region 52. According to example embodiments, the back contact 35 may be screen-printed on the back passivating oxide layer 41 on the back surface of the boron-doped emitter region 52. The back contact 35 may be applied using an aluminum paste, for example Monocrystal Analog 12D or the like. In the illustrated embodiment, the aluminum paste is screen-printed continuously across nearly the entire back surface of the boron-doped emitter region 52. In this embodiment, the aluminum paste of the back contact 35 may not be printed over a narrow border region 55 near the edges of the wafer (e.g., a border of approximately 1 mm wide). The solar cell 5 may optionally be placed on a belt furnace at a temperature in the range of 200 to 400 degrees Celsius in air ambient for 30 to 60 seconds to dry the printed paste. As noted above, however, various other embodiments of the manufacturing process may involve the formation of a back contact from other materials, such as gallium or indium.

Next, at operation 235, the substrate with the front and back contacts 30, 35 and front connections applied may be heated or co-fired in a belt furnace, such as an in-line belt furnace or the like. In the process of co-firing the structure, the front contacts 30 and front connections may fire through the front passivating oxide layer 40 and the antireflection layer 45 to form a physical connection with the front surface field layer 20. To facilitate firing through the oxide layer 40 and the antireflection layer 45, the front contacts 30 and front connections may contain frit, such as glass frit or the like. The glass frit in the paste used to form the front contacts 30 and front connections may melt at a temperature near 500 degrees Celsius and dissolve the underlying oxide layer 40 and antireflection layer 45. The firing temperature may be chosen such that the metal particles, such as silver, in the front contact paste form ohmic contact with the front surface field layer 20 without migrating below the depth of the front surface field layer.

During the co-firing at operation 235, aluminum from the back contact 35 may alloy with silicon from the p-type emitter layer and the n-type base layer 10, for example when the temperature exceeds the aluminum-silicon eutectic temperature of 577 degrees Celsius. In some embodiments, the temperature of the furnace may be high enough during the alloying so that the aluminum may effectively dissolve silicon. When the substrate cools following the co-firing, an aluminum-doped p⁺ silicon emitter layer 50 may form on the n-type base layer 10 by liquid phase epitaxial re-growth. However, in the illustrated embodiment, the boron-doped p⁺ silicon emitter layer 52 is formed on the full back surface of the n-type base layer 10. As such, the portion of the boron-doped p⁺ silicon emitter layer 52 overlapping the aluminum-doped p⁺ silicon emitter layer 50 will result in some boron dopant atoms being present in the predominantly aluminum-doped p⁺ silicon emitter layer 50. However, in other embodiments in which the boron-doped p⁺ silicon emitter layer 52 is not formed on the full back surface of the n-type base layer 10 (e.g., where it is only formed in the border region 55), boron dopant atoms may not be present in the aluminum-doped p⁺ silicon emitter layer 50.

As shown in FIG. 2c, a p-n junction 25 is formed at the interface of the n-type base layer 10 and the aluminum-doped p⁺ silicon emitter layer 50 and the boron-doped p⁺ silicon emitter layer 52 to create a back junction solar cell 5. The remainder of the aluminum back contact 35 may comprise an aluminum-silicon eutectic metal layer. In certain embodiments, a portion of the back contact 35 near the back of the solar cell 5 may comprise mostly aluminum.

The material of the back contact 35 may form a physical and electrical connection with the aluminum-doped p⁺ silicon emitter layer 50. In the process of co-firing the structure, the back contact 35 may fire through the back passivating oxide layer 41 to form a physical connection with the aluminum-doped p⁺ silicon emitter layer 50. As a result, the back passivating oxide layer 41 may be consumed by the back contact 35 material, for example by glass frit in the aluminum paste. The temperature profile may feature a high heating rate, in the range of 20 degrees Celsius per second to 150 degrees Celsius per second, that promotes formation of a uniform n-p⁺ interface between the back surface of the n-type base layer 10 and the emitter layer 50, 52.

Since the aluminum may serve as both the dopant for forming the aluminum-doped p⁺ silicon emitter layer 50 and the back contact 35, the back contact 35 may act as a self-aligning contact to the aluminum-doped p⁺ silicon emitter layer 50. The method may reduce the possibility of the back contact 35 shunting the p-n junction 25 for the same reason, namely that the aluminum of the back contact 35 is the source of the p-type dopant for forming the p-n junction 25. Additionally, the depth of the front surface field layer is of no real concern regarding shunting due to the location of the p-n junction 25 near the back surface of the solar cell 5.

To facilitate a solderable connection to the back side of the solar cell 5, back connections such as solderable pads or bus bars may be formed on the back surface of the back contact 35. For example, the back connections may be formed on the back contact 35 by applying copper foil on the back contact 35. In other embodiments, copper strips can be deposited (e.g., by a plasma process or by a sputtering process). In yet another embodiment, the back connections may be formed on the back contact 35 by applying silver soldering pads on the back of the back contact 35, for example Ferro LF33750 polymer Ag. Alternatively, a solderless interconnect method capable of bonding directly to the aluminum back contact 35 may be used, such as a conductive film. Yet another alternative is the deposition of solderable metal pads on the back aluminum surface by a plasma coating process. Solderable tin pads may also be applied.

The front and back connections may also become sintered, cured, or soldered to respective front and back contacts 30, 35 so that they are integrally connected and form good electrical connection to respective front and back sides of the solar cell 5. Connections may be adjoined via soldered wires to adjacent solar cells in a solar module and ultimately to a load to provide power thereto upon exposure of the solar cell to light.

### CONCLUSION

According to various embodiments of the manufacturing process described above, a back junction solar cell with improved emitter coverage may be formed. Many advantages may be realized by forming the back junction cell as described herein. For example, various embodiments exhibit improved short circuit current density (J_{sc}) and improved solar cell efficiency (e.g., at or exceeding 19% in certain embodiments). In addition, the quality of the p-n junction is also improved (e.g., an ideality factor close to 1 in certain embodiments) along with a corresponding increase in the cell's fill factor. The extended emitter area improves current collection near the edges of the wafer and also pushes the depletion region towards the edges of the wafer. In prior back junction cells not having cut edges, the depletion area on the back surface of the cell is exposed and unpassivated, which causes current to leak along the back surface, increase the recombination current, and reduce the fill factor of the cell. By contrast, the extended emitter layer of the back junction cells described herein better passivates the edges of the substrate and reduces the size of the depletion region. This reduces the leakage or recombination current in the cell and improves cell performance. In addition, the above-described method for manufacturing cells of this type is efficient and, in various embodiments, reduces or eliminates steps involving material subtraction (e.g., cutting, etching, scribing, laser ablation). In comparison to cells having cut edges, substantial manufacturing efficiencies are realized due to the elimination of the costly and inefficient cutting stage and conservation of silicon material.

Many modifications and other embodiments of the inventions set forth herein will come to mind to one skilled in the art to which these inventions pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of steps, elements, and/or materials than those explicitly described above are also contemplated as may be set forth in some of the appended claims. Accordingly, the specification and drawings are to be regarded in an illustrative rather than restrictive sense. Although specific terms are employed herein, they are used in a generic and descriptive sense only and not for purposes of limitation.

What is claimed is:

1. A solar cell of the back junction type having an emitter layer opposite an illuminated surface of the solar cell, the solar cell comprising:
a silicon substrate defining an n-type base layer and a p-type emitter layer underlying the n-type base layer so as to define a p-n junction at the interface of the p-type emitter layer and the n-type base layer; and
an aluminum back contact layer underlying the p-type emitter layer;
wherein the p-type emitter layer comprises:
at least one first region comprising aluminum dopant, wherein the area of the at least one first region at least partially overlaps the area of the aluminum back contact layer when viewed from beneath the aluminum back contact layer; and
at least one second region comprising a p-type dopant, at least a portion of the area of the at least one second region extending beyond the area of the at least one first region when viewed from beneath the back contact layer.

2. The solar cell of claim 1, wherein the p-type emitter layer covers the full back surface of the n-type base layer.

3. The solar cell of claim 2, wherein the aluminum back contact layer defines a border area between the outer edges of the aluminum back contact layer and the outer edges of the n-type base layer such that the at least one first region is defined within the edges of the n-type base layer; and
wherein the at least one second region surrounds first region and extends to each outer edge of the n-type base layer.

4. The solar cell of claim 3, wherein the at least one second region is formed on the full back surface of the n-type base layer.

5. The solar cell of claim 1, wherein the p-type dopant is boron.

6. The solar cell of claim 1, wherein the aluminum back contact layer is screen-printed and formed from an aluminum paste; and
wherein the at least one first region is formed from alloying of aluminum and silicon through liquid phase epitaxial regrowth.

7. The solar cell of claim 1, wherein the aluminum back contact layer is formed continuously along the surface of substrate.

8. The solar cell of claim 1, wherein the at least one second region is formed by ion implantation.

9. The solar cell of claim 1, further comprising:
an n⁺ front surface field layer overlying the n-type base layer;
a passivating oxide layer overlying the n⁺ front surface field layer;
an antireflection layer overlying the passivating oxide layer; and
one or more screen-printed contacts formed over the antireflection layer.

10. The solar cell of claim 1, wherein the cross-sectional area of the at least one first region is substantially aligned with the cross-sectional area of the aluminum back contact layer when viewed from beneath the back contact layer.

11. The solar cell of claim 1, wherein the at least one second region extends to one or more outer edges of the n-type base layer.

12. A method for forming a solar cell of the back junction type, comprising the steps of:
providing a n-type doped substrate to serve as an n-type base layer; and
fabricating a p-type emitter layer underlying the n-type base layer, wherein the step of fabricating the p-type emitter layer comprises:
doping at least one first region of a back surface of the substrate with a p-type dopant, the area of the at least one first region extending to one or more outer edges of the n-type base layer;
applying an aluminum back contact layer to the back surface of the substrate; and
alloying the aluminum back contact layer with at least one second region of the back surface of the substrate, the at least one second region being defined substantially within the perimeter of the at least one first region.

13. The method of claim 12, wherein the at least one first region and the at least one second region together cover the full back surface of the n-type base layer.

14. The method of claim 13, wherein the aluminum back contact layer is applied such that a border is defined between the outer edges of the aluminum back contact layer and the outer edges of the n-type base layer, and the at least one second region is defined within the edges of the n-type base layer.

15. The method of claim 14, wherein the at least one first region surrounds the at least one second region and extends to each of the outer edges of the n-type base layer.

16. The method of claim 12, wherein the at least one first region covers the full back surface of the n-type base layer.

17. The method of claim 12, wherein the p-type dopant is boron.

18. The method of claim 12, wherein the at least one first region is doped with the p-type dopant by ion implantation.

19. The method of claim 18, wherein the aluminum back contact layer is screen-printed and formed from an aluminum paste; and
the step of alloying the aluminum back contact layer with the at least one second region of the back side of the n-type base layer is accomplished by liquid phase epitaxial regrowth.

20. The method of claim 19, further comprising:
forming an n⁺ front surface field layer such that the n⁺ front surface field layer overlies the n-type base layer;
forming a passivating oxide layer over the n⁺ front surface field layer;
forming an antireflection coating over the passivating oxide layer; and
screen-printing one or more front contacts on the antireflection coating.

21. A solar cell of the back junction type having an emitter layer opposite an illuminated surface of the solar cell, the solar cell comprising:
an n-type base layer;
a p-type emitter layer underlying the n-type base layer and
a back contact layer underlying the p-type emitter layer;
wherein the p-type emitter layer comprises:
at least one first region doped with a first p-type dopant, wherein the area of the at least one first region at least partially overlaps the area of the back contact layer when viewed from beneath the back contact layer; and
at least one second region doped with a second p-type dopant, at least a portion of the area of the at least one second region extending beyond the area of the at least one first region to one or more outer edges of the n-type base layer when viewed from beneath the back contact layer.
